(19) United States
(12) Patent Application Publication
(10) Pub. No.: US 2014/0009165 A1
(43) Pub. Date: Jan. 9, 2014

(54) VOLTAGE MEASUREMENT DEVICE, VOLTAGE MEASUREMENT SYSTEM AND VOLTAGE MEASUREMENT METHOD

(71) Applicants: Motoki Miyazaki, Toyota-shi (JP); Akira Miyata, Tokorozawa-shi (JP)

(72) Inventors: Motoki Miyazaki, Toyota-shi (JP); Akira Miyata, Tokorozawa-shi (JP)

(73) Assignees: TOSHIBA IT & CONTROL SYSTEMS CORPORATION, Tokyo (JP); TOYOTA JIDOSHA KABUSHIKI KAISHA, Toyota-shi (JP)

(21) Appl. No.: 14/006,207

(22) PCT Filed: Mar. 21, 2012
(86) PCT No.: PCT/IB2012/000556

§ 371 Date: Sep. 19, 2013

(30) Foreign Application Priority Data
Mar. 24, 2011 (JP) 2011-065656

(51) Int. Cl. G01R 31/36

(52) U.S. Cl. CPC G01R 31/362
USPC 324/434

(57) ABSTRACT

A voltage measurement device that measures battery voltages of a plurality of single batteries connected in series has: a first voltage detection unit that detects the battery voltages; a storage unit that stores error information relating to a detection error between a voltage detected by the first voltage detection unit and a voltage detected by a second voltage detection unit of higher detection precision but lower detection speed than the first voltage detection unit; and a correction unit that, on the basis of the error information stored in the storage unit, corrects the battery voltages detected by the first voltage detection unit.

### BACKGROUND OF THE INVENTION

1. Field of the Invention

The invention relates to a voltage measurement device and the like that measures battery voltage in an assembled battery in which a plurality of single batteries are connected in series.

2. Description of Related Art

Conventional batteries for vehicles include assembled batteries in which a plurality of battery cells are connected is series. Over-discharge and over-charge of battery cells may result not only in impaired torque characteristics of an electric motor, and hence in impaired vehicle drivability, but also in reduced life of the battery cells. Therefore, it is necessary to monitor cell voltage in the battery cells, so that, in case of over-discharge or over-charge, such an anomaly is detected quickly so as to control charge and discharge accordingly.

Japanese Patent Application Publication No. 2009-069056 (JP 2009-069056 A) discloses a cell voltage monitoring device that monitors anomalies in battery cells of a multi-cell series battery, wherein a cell voltage anomaly detection circuit is activated immediately after start of a monitor cycle for an arbitrary battery cell, and it is determined whether cell voltage deviates from a normal range.

In the configuration of JP 2009-069056 A, however, measurement of cell voltages takes some time. Also, anomalies such as over-charge and over-discharge may be overlooked upon a drop in the measurement precision of cell voltage.

The invention provides a voltage measurement device, a voltage measurement system and a voltage measurement method that combine shortening of the measurement time of battery voltage with enhanced measurement precision.

A voltage measurement device according to a first aspect of the invention is a voltage measurement device that measures battery voltages of a plurality of single batteries connected in series, the device having: a first voltage detection unit that detects the battery voltages; a storage unit that stores error information relating to a detection error between a voltage detected by the first voltage detection unit and a voltage detected by a second voltage detection unit of higher detection precision but lower detection speed than the first voltage detection unit; and a correction unit that, on the basis of the error information stored in the storage unit, corrects the battery voltages detected by the first voltage detection unit.

In the configuration of the voltage measurement device according to the first aspect, the detection error may be a voltage difference obtained when the first voltage detection unit and the second voltage detection unit respectively detect a voltage of a reference power source. Such a configuration allows acquiring accurate error information.

In the configuration of the voltage measurement device according to the first aspect, the first voltage detection unit may include a plurality of differential amplifiers provided so as to correspond to the single batteries; and each of the differential amplifiers may acquire each of the battery voltages at an identical timing. In such a configuration, battery voltages are acquired concurrently, and hence detection speed can be reliably increased.

In the above configuration, there may be further provided an averaging processing unit that averages respective battery voltages consecutively outputted from the differential amplifiers; such that the correction unit may correct, on the basis of the error information, the battery voltages averaged by the averaging processing unit. Such a configuration allows further enhancing measurement precision of battery voltages.

In the configuration of the voltage measurement device according to the first aspect, the detection precision of the first voltage detection unit may fluctuate with temperature. Loss of measurement precision can be averted through correction on the basis of the error information, even if detection precision by the first voltage detection unit drops accompanying changes in temperature.

A voltage measurement system according to a second aspect of the invention is a voltage measurement system that measures battery voltages of a plurality of single batteries connected in series, the system having: a reference power source; a first voltage detection unit that detects the battery voltages; a second voltage detection unit of higher detection precision but lower detection speed than the first voltage detection unit; a storage unit that stores, as error information, a voltage difference obtained when the first voltage detection unit and the second voltage detection unit respectively detect a voltage of the reference power source; and a correction unit that, on the basis of the error information stored in the storage unit, corrects the battery voltages detected by the first voltage detection unit.

A voltage measurement method according to a third aspect of the invention includes measuring a voltage of a reference power source, using a first voltage detection unit; measuring a voltage of the reference power source, using a second voltage detection unit of higher detection precision but lower detection speed than the first voltage detection unit; storing in a storage unit, as error information, a difference between the voltage of the reference power source measured by the first voltage detection unit and the voltage of the reference power source measured by the second voltage detection unit; concurrently measuring battery voltages of a plurality of single batteries connected in series, using the first voltage detection unit; and correcting, on the basis of the error information stored in the storage unit, the battery voltages measured by the first voltage detection unit.

That above aspects of the invention allow achieving both shortening of the measurement time of battery voltage and enhanced measurement precision.

Features, advantages, and technical and industrial significance of exemplary embodiments of the invention will be described below with reference to the accompanying drawings, in which like numerals denote like elements, and wherein:

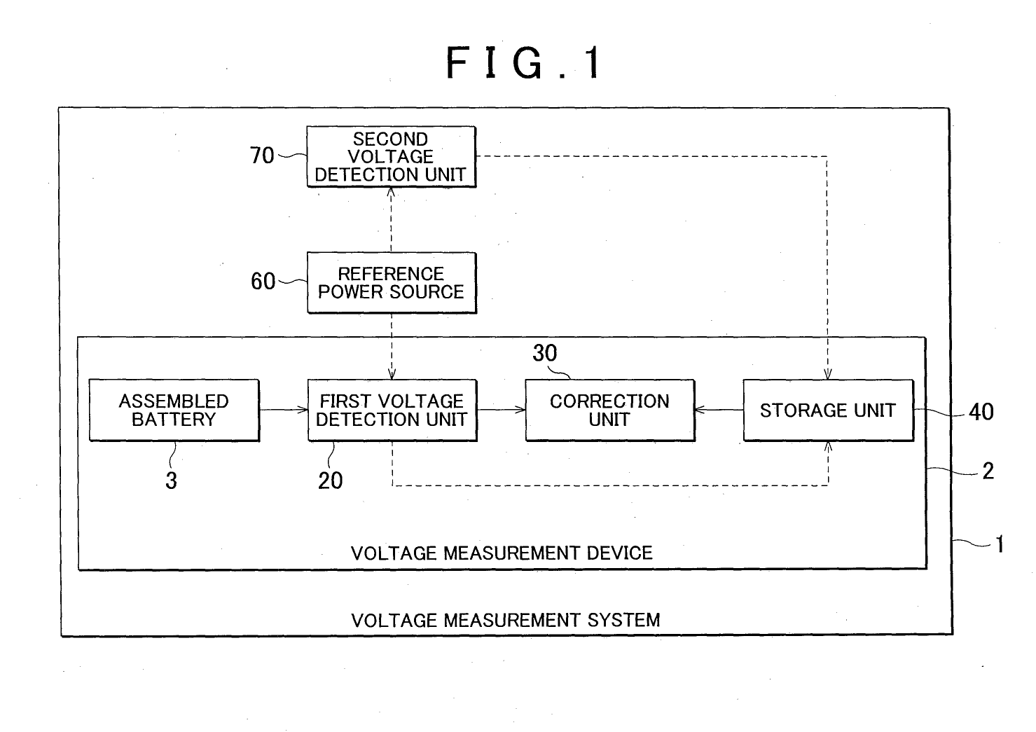

FIG. 1 is a functional block diagram of a voltage measurement system having a voltage measurement device according to an embodiment of the invention;

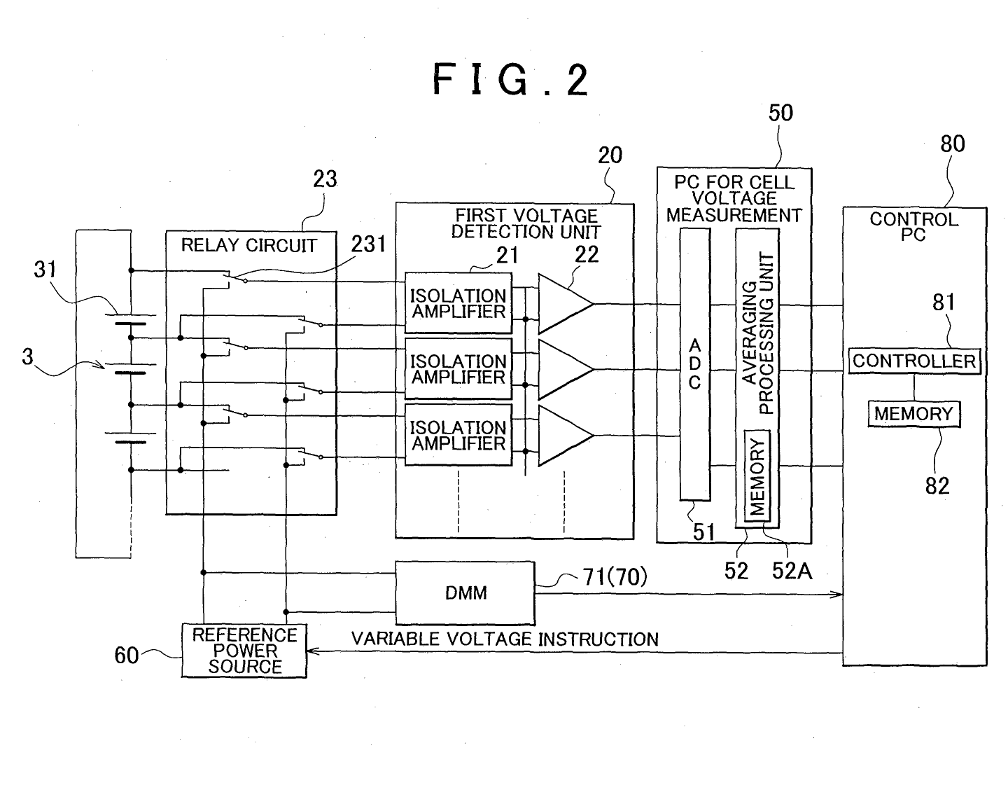

FIG. 2 is a circuit diagram illustrating a hardware configuration of a voltage measurement system according to an embodiment of the invention;

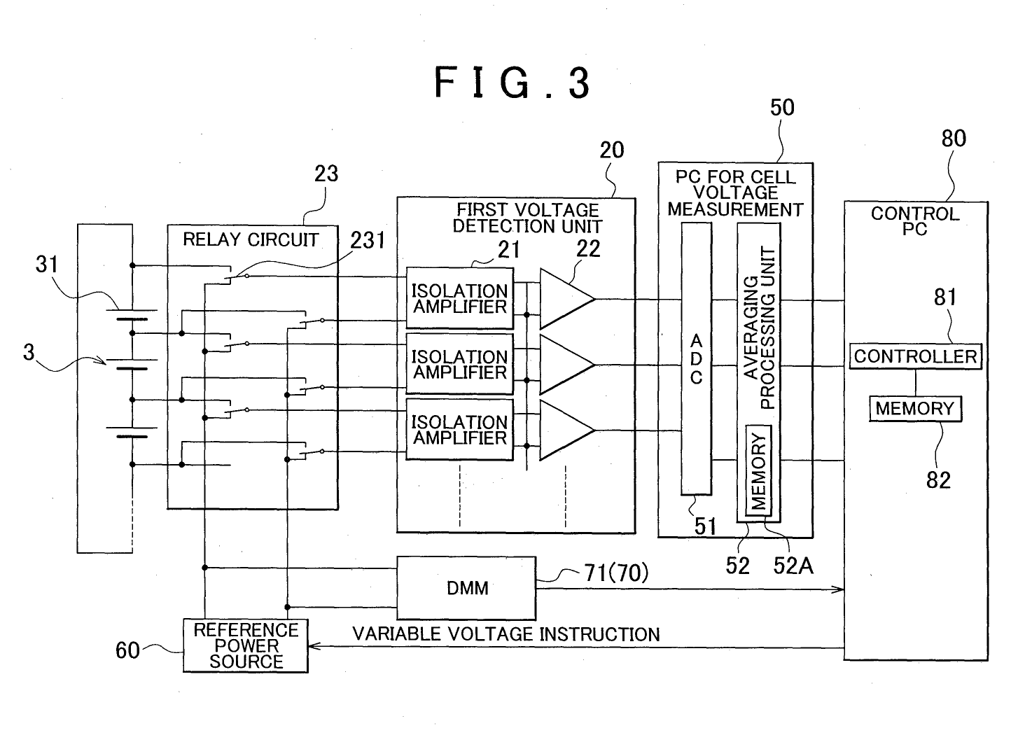

FIG. 3 is a circuit diagram illustrating a hardware configuration upon acquisition of error information according to an embodiment of the invention;

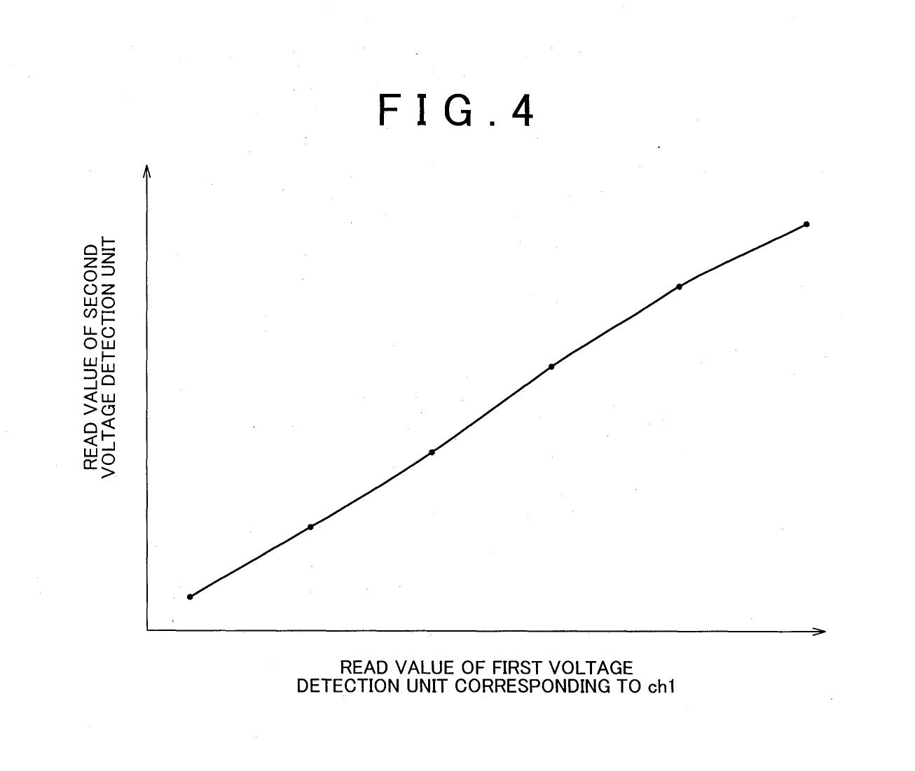

FIG. 4 is a schematic diagram illustrating schematically error information according to an embodiment of the invention;

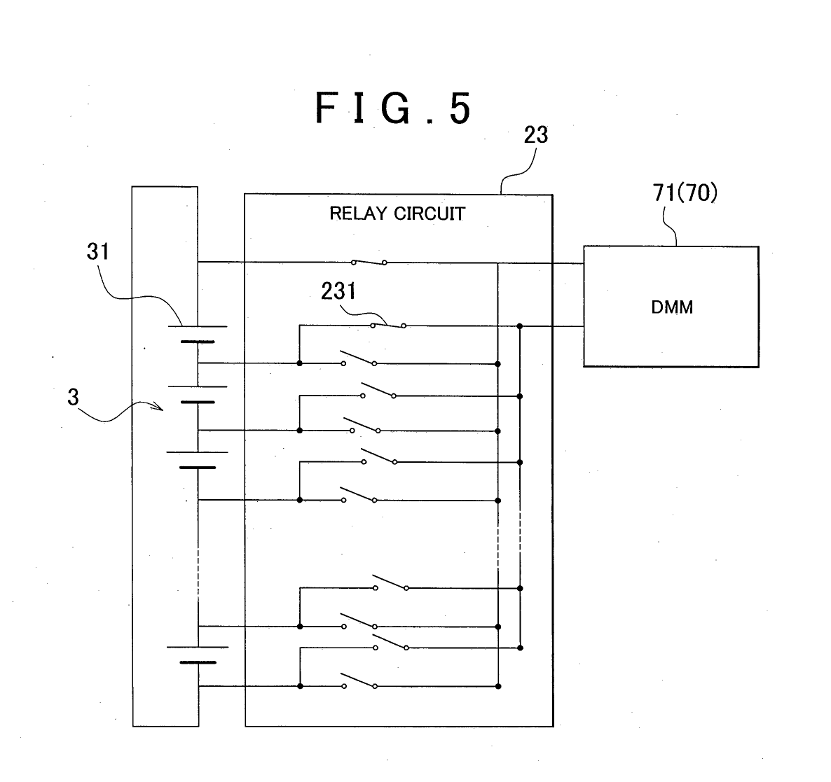

FIG. 5 is a circuit diagram of the voltage measurement device in a comparative example;

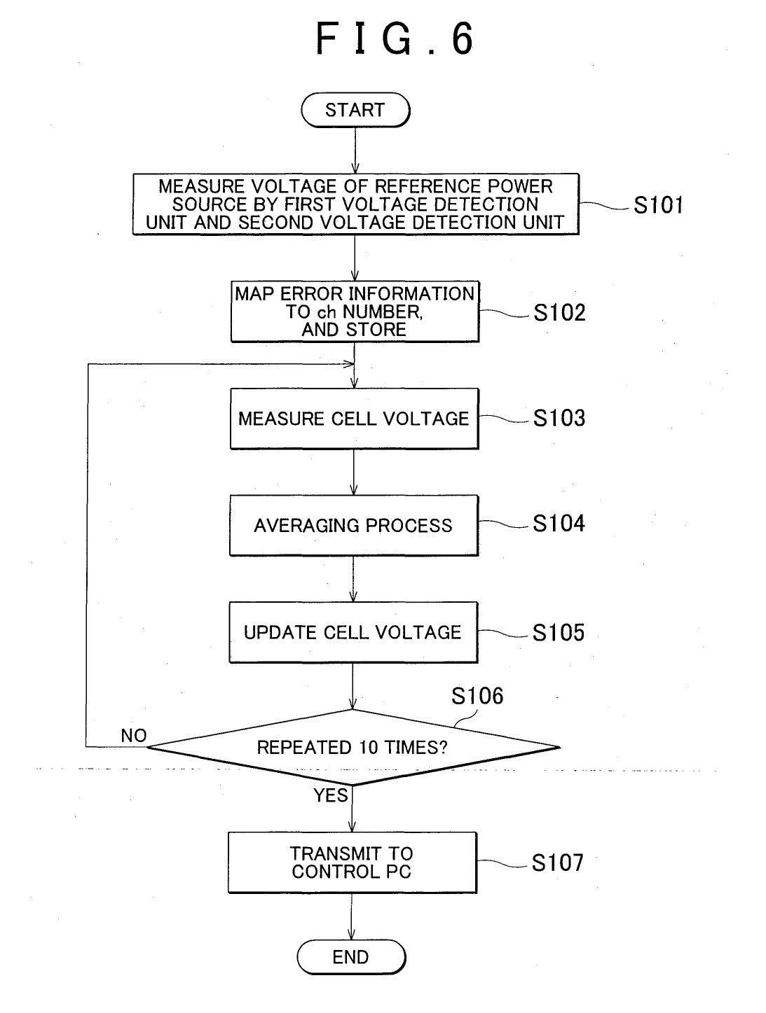

FIG. 6 is a flowchart illustrating a cell voltage measurement method according to an embodiment of the invention; and

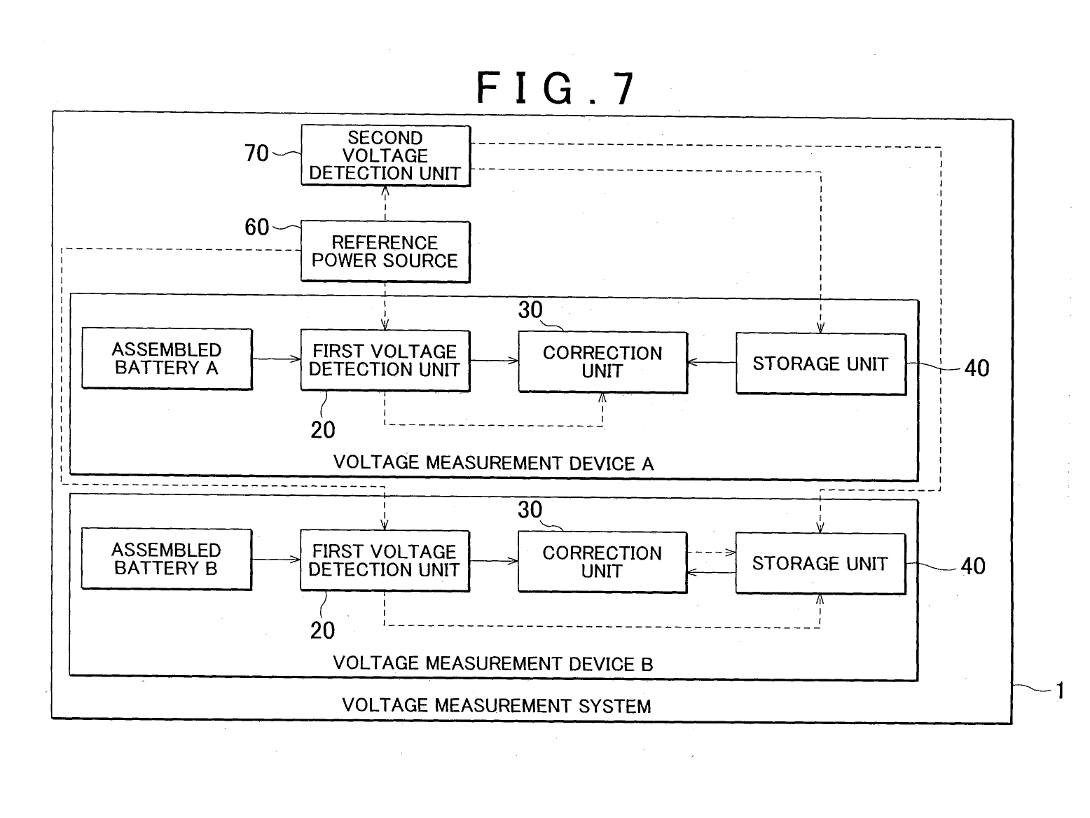

FIG. 7 is a functional block diagram of a voltage measurement system in a case of measurement of cell voltages of two different assembled batteries, according to an embodiment of the invention.

### DETAILED DESCRIPTION OF EMBODIMENTS

A voltage measurement system that includes a voltage measurement device according to the present embodiment will be explained next with reference to FIG. 1 and FIG. 2. FIG. 1 is a functional block diagram of the voltage measurement system, wherein the dotted line indicates the flow of signals upon determination of error information in a first and a second voltage detection unit, and the solid lines denote the flow of signals upon measurement of the cell voltage (battery voltage) of each battery cell (single battery). FIG. 2 is a circuit diagram illustrating an example of hardware in the voltage measurement system.

With reference to FIG. 1, the voltage measurement system 1 has a voltage measurement device 2, a reference power source 60 and a second voltage detection unit 70. The voltage measurement device 2 has an assembled battery 3, a first voltage detection unit 20, a correction unit 30 and a storage unit 40. As illustrated in FIG. 2, the assembled battery 3 is configured through connection in series of a plurality of battery cells 31. The battery cells 31 may be secondary batteries such as lithium ion batteries, nickel hydride batteries or the like.

The first voltage detection unit 20 measures the cell voltage of the battery cells 31. The first voltage detection unit 20 measures also the voltage of the reference power source 60. The second voltage detection unit 70 measures the voltage of the reference power source 60. The second voltage detection unit 70 has higher detection precision, and lower detection speed, than the first voltage detection unit 20. The storage unit 40 stores, as error information, a voltage difference obtained when the first voltage detection unit 20 and the second voltage detection unit 70 respectively detect the voltage of the reference power source 60. On the basis of the error information stored in the storage unit 40, the correction unit 30 corrects the respective cell voltages detected by the first voltage detection unit 20.

In the above configuration, the cell voltage in each battery cell 31 is detected by the first voltage detection unit 20. The measurement speed of voltage measurement can be made higher as a result. Also, the cell voltage detected by the first voltage detection unit 20 is corrected on the basis of error information stored in the storage unit 40. The measurement precision in voltage measurement can be enhanced as a result.

An example of a hardware configuration for realizing the voltage measurement device 2 will be explained next with reference to FIG. 2. The first voltage detection unit 20 has a plurality of isolation amplifiers 21 and a plurality of differential amplifiers 22. The isolation amplifiers 21 and the differential amplifiers 22 are provided for respective battery cells 31. The isolation amplifiers 21 isolate “ch” from each other. The differential amplifiers 22 amplify an input signal up to an analog to digital converter (ADC) input rating, and output the signal to an ADC 51 mounted on a subsequent PC 50 for cell voltage measurement. The isolation amplifiers 21 and the differential amplifiers 22 are analog circuits, and hence exhibit variability in measurement precision on account of temperature changes, and also the estimation precision thereof decreases as a result of changes over time. Therefore, the first voltage detection unit 20 has characteristically high detection speed but low detection precision.

The relay circuit 23 is positioned between the assembled battery 3 and the first voltage detection unit 20. The relay circuit 23 has a plurality of relays 231. The relays 231 are provided for respective isolation amplifiers 21. The relays 231 switch between a state of connection to respective battery cells 31 and a state of connection to the reference power source 60. In the present embodiment, the cell voltages of all battery cells 31 are measured concurrently, and hence all relays 231 are connected to corresponding battery cells 31.

The ADC 51 is connected to the averaging processing unit 52 via a peripheral components interconnect (PCI) bus, and concurrently feeds the cell voltages of the battery cells 31 to the averaging processing unit 52, at cycles of 3 to 4 ms. The averaging processing unit 52 may be implemented in the form of a central processing unit (CPU) or a micro processing unit (MPU). The averaging processing unit 52 is provided with a memory 52A. The CPU or the MPU in the averaging processing unit 52 stores, in the memory 52A, information relating to the cell voltages outputted by the respective differential amplifiers 22, and, upon reception of subsequent cell voltages, averages the received cell voltages with the cell voltages stored in the memory 52A, and updates the cell voltages stored in the memory 52A. Cell voltages are updated every time that information relating to cell voltages is received. An application specific integrated circuit (ASIC) may be used that performs, in circuit form, at least part of the process that is executed by the CPU or MPU. Performing thus the averaging process of the cell voltages concurrently results in a faster process.

The number of averaging processes carried out can be appropriately decided by a person skilled in the art from the viewpoint of enhancing measurement precision. In a case where, for instance, the number of averaging processes is 10, then the measurement time of all cell voltages can be shortened to just 30 to 40 ms. Drops in measurement speed can be curtailed even if the number of battery cells 31 is increased, since the averaging process of the cell voltages is performed concurrently.

A control PC 80 has a controller 81 and a memory 82. The controller 81 controls the entire control PC 80. The controller -81 may be a CPU or an MPU, or may be an ASIC that performs, in circuit form, at least part of the process that is executed by the CPU or MPU. The memory 82 stores error information being a voltage difference obtained when the first voltage detection unit 20 and the second voltage detection unit 70 respectively detect the voltage of the reference power source 60. The memory 82 may be a readable recording medium, and may be for instance a random access memory (RAM).

The correspondence between the functional block of FIG. 1 and the hardware configuration of FIG. 2 is explained next. The process performed by the correction unit 30 in FIG. 1 may be executed through cooperation between the memory 82 and the controller 81 of the control PC 80. Specifically, the controller 81 corrects the respective cell voltages detected by the first voltage detection unit 20, on the basis of the error information stored in the memory 82.

The process performed by the storage unit 40 in FIG. 1 may be carried out through cooperation between the memory 82 and the controller 81 of the control PC 80. That is, the controller 81 calculates a difference between the voltage of the reference power source 60 as detected by the first voltage detection unit 20 and the voltage of the reference power source 60 as detected by the second voltage detection unit 70, and stores the difference, as error information, in the memory 82. The storage unit 40 may be positioned outside the control PC 80. In this case, the control PC 80 corrects the cell voltages by acquiring, through communication, the error information stored in the storage unit 40.

The method for acquiring the error information stored in the storage unit 40 is explained next with reference to FIG. 3. FIG. 3 is a diagram corresponding to FIG. 2. The configuration in FIG. 3 is different from that of FIG. 2 in that now all the relays 231 are positioned at a connection position of connecting the first voltage detection unit 20 and the reference power source 60.

The second voltage detection unit 70 measures the voltage of the reference power source 60. The second voltage detection unit 70 may be a digital multimeter (DMM) 71. The control PC 80 acquires a voltage outputted by the DMM 71.

The control PC 80 modifies the voltage of the reference power source 60 within a predefined range. The predefined range may be the working voltage of the battery cells 31; alternatively, the voltage may be for instance sequentially modified in 1 V intervals, from 0 V to 5 V.

The control PC 80 acquires the detection results by the first voltage detection unit 20 and a the DMM 71 while modifying the voltage of the reference power source 60 in 1 V intervals, from 0 V to 5 V, and stores the result, in the storage unit 40, as error information mapped to the channel number of the relays 231. FIG. 4 is a schematic diagram illustrating schematically the error information in the format of a data table. Values other than the acquired voltage values can be worked out by straight line approximation. Error information of all channels can be acquired by executing these operations for all the channels. The format of the error information may be other than a data table (for instance, a function expression).

FIG. 5 is a circuit diagram of the voltage measurement device in a comparative example. Constituent elements identical to those of the embodiment are denoted with the same reference numerals. In the comparative example, the cell voltages of the battery cells 31 are acquired by the DMM 71. The first stage of the. DMM 71 is an analog circuit, and hence measurement errors occur as a result of temperature changes as in the case of the differential amplifiers 22. However, the DMM 71 is also a dedicated measurement device, and is well equipped with a compensation circuit, and hence the measurement precision thereof is high. The measurement time upon measurement of the cell voltages, however, is very long, since the cell voltages must be measured at different timings through consecutive switching-on of the relays 231 in a sequence set beforehand.

In a case where, for instance, the switching cycle of the relays 231 is 20 ms/ch, and the measurement time of the DMM 71 is 17 ms/ch, then it takes a total measurement time of 2072 ms to measure the cell voltages of 56 battery cells 31. That is, the second voltage detection unit 70 is characterized by having higher measurement precision, but incurring a longer measurement time, than the first voltage detection unit 20.

An explanation follows next, with reference to the flowchart of FIG. 6, of a measurement method for measuring cell voltages in the present embodiment. In step S101, the first voltage detection unit 20 and the second voltage detection unit 70 measure the voltage of the reference power source 60. In step S102, the control PC 80 stores, in the storage unit 40, the measurement result of step S101, as error information.

In step S103, the first voltage detection unit 20 concurrently measures the cell voltages of the battery cells 31, amplifies the measured cell voltages up to an ADC input rating, and outputs the cell voltages to the ADC 51. In step S104, the averaging processing unit 52 averages the cell voltages received from the ADC 51 and the cell voltages stored in the memory 52A, and in step S105, stores the obtained averaged values, as new cell voltages, in the memory 52A. If no cell voltage is stored in the memory 52A, the cell voltages received from the ADC 51 are stored, as they are, in the memory 52A.

In step S106, the averaging processing unit 52 determines whether the number of averaging processes reaches 9 processes (i.e., whether the number of measurements of cell voltage reaches 10 measurements). If the number of measurements reaches 10 measurements, the process proceeds to step S107; else, the process returns to step S103. In step S107, the averaging processing unit 52 maps the cell voltages of the battery cells 31, as stored in the memory 52A, to the cell numbers of the battery cells 31, and outputs the mapped cell voltages to the control PC 80.

The controller 81 of the control PC 80 reads error information from the storage unit 40, and corrects the cell voltages. In a case where, for instance, the measured cell voltage of the battery cell 31 for ch1 is 3.6 V, the cell voltage is recorded in the form of a correct voltage value after correction of the voltage value of the second voltage detection unit 70 that corresponds to 3.6 V, with reference to FIG. 4. The above method allows enhancing measurement precision as compared with a case in which cell voltage is measured by the first voltage detection unit 20 alone. Also, the measurement speed can be made higher than in an instance where cell voltage is measured by the second voltage detection unit 70 alone.

### (Variation 1)

In the above-described embodiment, an instance has been explained in which there are measured cell voltages of one assembled battery, but the invention of the present application can be used also in instances of measurement of cell voltages in a plurality of assembled batteries. FIG. 7, which corresponds to FIG. 1, is a functional block diagram of a voltage measurement system in a case of measurement of cell voltages of two different assembled batteries. Constituent elements that have the same function as those in the above embodiment are denoted with the same reference numerals.

With respect to FIG. 7, a voltage measurement device A measures the cell voltage of battery cells that make up an assembled battery A, and a voltage measurement device B measures the cell voltage of battery cells that make up an assembled battery B. In the present variation, the reference power source 60 is shared by the voltage measurement device A and the voltage measurement device B. Therefore, costs can be reduced, since there is no increase in the, number of reference power sources 60. Cell voltage measurement of the assembled battery A and cell voltage measurement of the assembled battery B can be performed concurrently, so that measurement speed can be increased as a result.

### (Variation 2)

In the above-described embodiment, the cell voltages in the battery cells 31 are measured a plurality of times, and average values thereof are used as cell voltages before correction in the correction unit 30. However, the invention is not limited thereto, and the averaging process may be omitted. In this case, the cell voltages outputted by the first voltage detection unit 20 are corrected by the correction unit 30.

### (Variation 3)

In the above-described embodiment, an instance has been explained in which the cell voltages of battery cells are measured, but the invention is not limited thereto, and may be used also in another single battery. This other single battery may be a battery module in which a plurality of battery cells are connected. That is, the invention can be used in an instance of measurement of module voltages (battery voltages) of respective battery modules.

1. A voltage measurement device that measures battery voltages of a plurality of single batteries connected in series, comprising:
a first voltage detection unit that detects the battery voltages;
a storage unit that stores error information relating to a detection error between a voltage detected by the first voltage detection unit and a voltage detected by a second voltage detection unit of higher detection precision but lower detection speed than the first voltage detection unit; and
a correction unit that, on the basis of the error information stored in the storage unit, corrects the battery voltages detected by the first voltage detection unit.

2. The voltage measurement device according to claim 1, wherein the detection error is a voltage difference obtained when the first voltage detection unit and the second voltage detection unit respectively detect a voltage of a reference power source.

3. The voltage measurement device according to claim 1, wherein
the first voltage detection unit includes a plurality of differential amplifiers provided so as to correspond to the single batteries, and
each of the differential amplifiers acquires each of the battery voltages at an identical timing.

4. The voltage measurement device according to claim 3, further comprising: an averaging processing unit that averages respective battery voltages consecutively outputted from the differential amplifiers,
wherein the correction unit corrects, on the basis of the error information, the battery voltages averaged by the averaging processing unit.

5. The voltage measurement device according to claim 1, wherein the detection precision of the first voltage detection unit fluctuates with temperature.

6. A voltage measurement system that measures battery voltages of a plurality of single batteries connected in series, comprising:
a reference power source;
a first voltage detection unit that detects the battery voltages;
a second voltage detection unit of higher detection precision but lower detection speed than the first voltage detection unit;
a storage unit that stores, as error information, a voltage difference obtained when the first voltage detection unit and the second voltage detection unit respectively detect a voltage of the reference power source; and
a correction unit that, on the basis of the error information stored in the storage unit, corrects the battery voltages detected by the first voltage detection unit.

7. A voltage measurement method, comprising:
measuring a voltage of a reference power source, using a first voltage detection unit;
measuring a voltage of the reference power source, using a second voltage detection unit of higher detection precision but lower detection speed than the first voltage detection unit;
storing in a storage unit, as error information, a difference between the voltage of the reference power source measured by the first voltage detection unit and the voltage of the reference power source measured by the second voltage detection unit;
concurrently measuring battery voltages of a plurality of single batteries connected in series, using the first voltage detection unit; and
correcting, on the basis of the error information stored in the storage unit, the battery voltages measured by the first voltage detection unit.
